(19) United States
(12) Patent Application Publication
(10) Pub. No.: US 2025/0365023 A1
(43) Pub. Date: Nov. 27, 2025

(54) System and Methods for Least Reliable Bit (LRB) Identification

(71) Applicant: RETYM INC., Cupertino, CA (US)

(72) Inventors: Micha Anholt, Tel Aviv (IL); Ben Shilo, Rosh Ha'Ain (IL)

(21) Appl. No.: 18/874,112

(22) PCT Filed: Jun. 20, 2023
(86) PCT No.: PCT/US2023/068744

§ 371 Date: Dec. 12, 2024

Related U.S. Application Data
(60) Provisional application No. 63/354,040, filed on Jun. 21, 2022.

(51) Int. Cl. H03M 13/39

(52) U.S. Cl. CPC H03M 13/3927

(57) ABSTRACT

A least reliable bit (LRB) identification approach based on a cumulative distribution function (CDF) is disclosed. In some embodiments, a receiver includes a detector and a decoder. The detector is configured to receive a codeword and determine a list of reliability values for the bits included in the codeword. The decoder is configured to receive, from the detector, the codeword and the list of reliability values, compute a list of CDFs of the reliability values for the codeword, identify, from the CDF list, a group including a specific number of LRBs that have the reliability values within a threshold range, and determine a location of each LRB of the group in the codeword.

### CROSS REFERENCE TO RELATED APPLICATION

This application claims the benefit of U.S. Provisional Patent Application No. 63/354,040, titled “System and Methods for Least Reliable Bit (LRG) Identification” filed Jun. 21, 2022, the entire contents of which are incorporated by reference herein.

### TECHNICAL FIELD

This disclosure relates to a decoding system for identifying LRBs of a codeword based on a cumulative distribution function (CDF).

### BACKGROUND

A challenging task in communication systems is to accurately decode codewords received via noisy channels. Before a message is transmitted, a sender may encode the message with error-correction code (e.g., adding redundant bits or parity bits to the message) forming the codewords. A receiver receives the message transmitted via a computer network to perform decoding (e.g., error correction process) to retrieve the original message. Typically the receiver may perform hard decision decoding or soft decision decoding. Hard decision decoding or hard decoding takes a stream of bits and decodes each bit by considering it as definitely one or zero, for example, by sampling the received pulses and comparing the voltages to threshold values. On the other hand, soft decision decoding or soft decoding treats the received signal as a probability distribution and calculates the likelihood of each possible transmitted bit (e.g., soft values) based on the characteristics of the received signal. The soft values are then processed to obtain the hard values of the bits, i.e., zero or one. Often soft decoding may achieve higher accuracy and reliability but in the price of complexity. Therefore, a simplified and effcient soft decoding approach is desired

### SUMMARY

To address the aforementioned shortcomings, a least reliable bit (LRB) identification based on a cumulative distribution function (CDF) is disclosed. In some embodiments, a receiver in a communication systems includes a detector and a decoder. The detector is configured to receive a codeword and determine a list of reliability values for the bits included in the codeword. The detector is configured to receive, from the detector, the codeword and the list of reliability values, compute a list of CDFs of the reliability values for the codeword, identify, from the CDF list, a group including a specific number of LRBs that have the reliability values within a threshold range, and determine a location of each LRB of the group in the codeword.

The above and other preferred features, including various novel details of implementation and combination of elements, will now be more particularly described with reference to the accompanying drawings and pointed out in the claims. It will be understood that the particular methods and apparatuses are shown by way of illustration only and not as limitations. As will be understood by those skilled in the art, the principles and features explained herein may be employed in various and numerous embodiments.

### BRIEF DESCRIPTION OF THE DRAWINGS

The disclosed embodiments have advantages and features which will be more readily apparent from the detailed description, the appended claims, and the accompanying figures (or drawings). A brief introduction of the figures is below.

FIG. 1 illustrates an exemplary communication system with error correction, according to some embodiments.

FIG. 2 illustrates an exemplary input codeword associated with reliability information, according to some embodiments.

FIG. 3 illustrates an exemplary LRB identification result from applying the present approach on the exemplary input codeword of FIG. 2, according to some embodiments.

FIG. 4 illustrates an exemplary cumulative distribution function (CDF) of the exemplary codeword in FIG. 2.

FIG. 5 illustrates an exemplary method for LRB identification, according to some embodiments.

FIG. 6 illustrates an exemplary method of using an oFEC decoder to apply CDF-based LRB identification, according to some embodiments.

FIG. 7 illustrates an exemplary high-level open forward error correction (oFEC) decoder, according to some embodiments

FIG. 8 illustrates an exemplary oFEC decoding process using Chase decoder, according to some embodiments.

FIG. 9 illustrates an exemplary process for CDF-based LRB identification, according to some embodiments.

### DETAILED DESCRIPTION

The Figures (FIGS.) and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

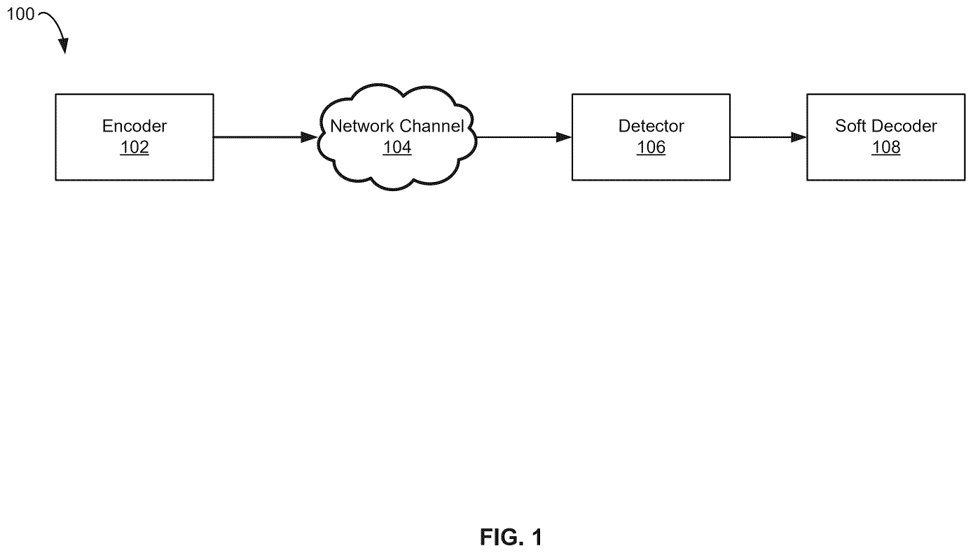

FIG. 1 illustrates an exemplary communication system 100 with error correction. A communication system (wireless or wired) often relies on error correction mechanisms (e.g., forward error correction (FEC)) to control errors when information is transmitted over noisy communication channels. As shown in FIG. 1, a sender (e.g., encoder 102) encodes the input data (e.g., information, messages) using error correcting codes. The encoded data (i.e., codewords) is transmitted via a noisy channel or transmission link 104 to a receiver.

FEC is a coding scheme that improves the bit error rate of communication links by adding redundant information (e.g., parity bits) to the input data at the transmitter such that the receiver can use the redundant information to detect and correct errors introduced in the transmission link. FEC error correcting codes can be block codes, convolutional codes, or concatenated codes. Block codes operate on fixed-size packets, convolutional codes operate on streams with arbitrary length, and concatenated codes generally have properties of block codes and/or convolutional codes. The present disclosure mainly focuses on decoding concatenated codes and/or block codes, such as Turbo product codes (TPC), open FEC (oFEC) defined in international telecommunication union (ITU) G.709.3, etc.

The receiver may detect and receive the encoded data, including any changes made by noise during transmission, and then decode the received data to retrieve the sender's input information. Decoding error-correcting codewords typically includes hard decoding or soft decoding Soft decoding can usually achieve better error correction capability than hard decoding for a given signal-to-noise ratio (SNR) or input error rate, but often in the price of complexity such as in power, area, latency, etc, as described below with respect to the Chase algorithm. A choice of using soft decoding or hard decoding may depend on a target error rate, a noise level, as well as many system considerations. It is not always easy or possible to determine the soft values used in soft decoding. The disclosure herein presents an optimized, computionally efficient soft decoding approach that outperforms in error correction.

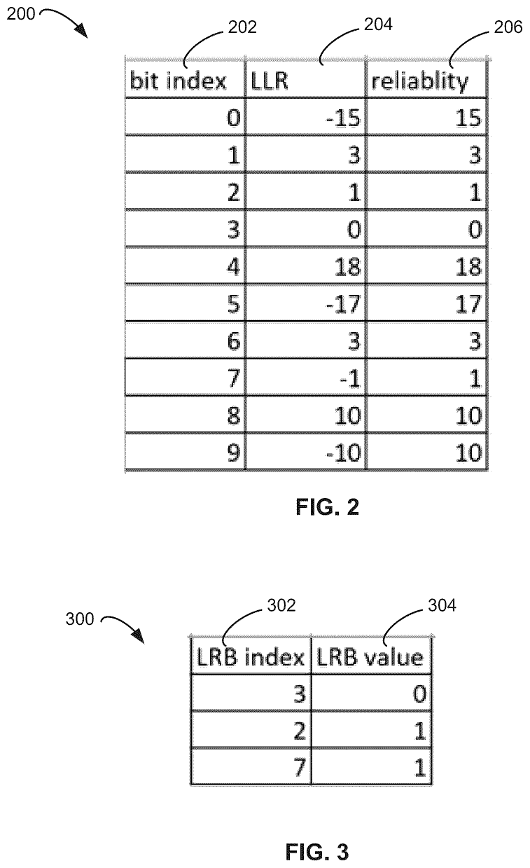

In FIG. 1, the receiver includes a detector 106 and a soft decoder 108. In some embodiments, detector 106 may detect and receive a codeword transmitted over channel 104 and calculate reliability information for each bit of the codeword. The reliability information may include a cumulative distribution function (CDF), a log likelihood ratio (LLR), etc., as discussed below in FIGS. 2-4. Soft decoder 108 may receive the reliability information from detector 106 and decode the codeword to retrieve the original input information/message from sender/encoder 102. In some embodiments, soft decoder 108 may be configured to determine a set of test patterns based on the reliability information and determine how to perform hard decision coding on pattern(s) in the set of test patterns. It should be noted that FIG. 1 is depicted for illustration, other components (e.g., hard decoder) may be included in communication system 100. For example, one or more hard decoders (not shown) may be part of detector 106 to assist decoding, and/or be included in soft decoder 108 (e.g., a Chase decoder) to determine the reliability information.

When the received codewords or codes are decoded using soft decoding (typically, with iterative soft decoding), one of the most popular algorithms for soft decoding a single component code is the Chase algorithm. The main idea of the Chase algorithm is that, if a word or message decoded by a hard decoder (i.e., traditional hard decision) contains an error, then one of its “closest” words will most likely match the transmitted message (i.e., the sender's input information). Traditionally an Euclidean distance between the received codeword and the original codeword is calculated, and an exhaustive search is conducted to find a coderword. The decoding methods of this type quickly becomes prohibitive because of the unbearable computation complexity associated with the increase of the codeword size. The Chase algorithm is a maximum-likelihood (ML) bit estimation, which is based on the observation that at a high SNR, a ML codeword is located, with a very high probability, in a sphere with a specific radius centered on a specific point (e.g., determined based on the SNR and the received code). To reduce the number of reviewed codewords, only the set of most probably codewords (i.e., “closest” codewords) within the sphere are selected. Further descriptions regarding the Chase algorithm are shown in R. M. Pyndiah, Near-Optimum Decoding of Prodcut Codes: Block Turbo Codes. IEEE Transactions on Communications, Vol. 46, No. 8 (1998), which is incorporated by reference in its entirety.

In general, the Chase algorithm enumerates a set of selected bit patterns that are decoded with a hard decoder. The results from applying the hard decoder over all the bit patterns are used to generate soft decision metrics or reliability information, e.g., log likelihood ratios (LLRs) for the bits in the codeword. In some embodiments, the patterns may be generated by taking the bits in the hard pattern (slicing of soft bits) and flipping some of the least reliable bits (LRBs). Different combinations of the least reliable bits are processed, and the output of soft decoder is the candidate word with the best soft decision metric.

The Chase algorithm may improve performance in some way but with apparent drawbacks. The Chase algorithm requires the identification of the least reliable bits (or least reliable positions). Using the Chase algorithm, the entire codeword has to be analyzed to find a specified number n of least reliable bits (LRBs).

A bit's reliability is often measured by the absolute value of the bit's LLR. With the Chase algorithm, LRB identification is based on reading the list of LLR per bit and comparing the LLR of each bit to maintain a dynamic list of NLRBs. The dynamic list is updated until every bit of the codeword is scanned. The final result is the list of least reliable bits. The list may also include the bit location and bit LLR/reliability associated with the least reliable bits. Here, a significant amount of hardware and other computing resources may be needed to implement a high-rate decoder.

The present systems and methods for LRB identification disclosed herein address the foregoing drawbacks and improve the performance of error correction decoding. Prior art systems (e.g., Chase) use a one-pass (e.g., on read) algorithm to find the LRBs with a large decision tree, thereby causing substantial amount of power consumption and/or large latency. In the present system, comparison operation(s) for LRB identification is against fixed values, and the logic decision tree is greatly simplified. In some embodiments, the present system uses a two-pass algorithm to simplify the identification process and reduce power usage. The two-pass typically can be achieved when the decoding processing is separated between write and read, as compared to the one-pass on read in Chase decoders. The present system, therefore, reduces complexity and latency and increases efficiency and accuracy when applied in identifying LRBs of codewords in a decoding process.

Additionally, the present approach can be used in any system that needs to identify extreme values in data, which is particularly advantageous in error correcting decoding situations where the resolution of the reliability is low, and only a limited amount of values are available for the CDF determination.

It should be noted the “Chase decoder” or “Chase algorithm” in this description is referred to a general soft decoder that enumerates over patterns, as used in the error correction literature. They are not necessarily referred to as one of the original Chase options.

FIG. 2 illustrates an exemplary input codeword 200 with associated reliability information. Codeword 200 is an input to either detector 106 or soft decoder 108 of the receiver. The input codeword 200 may contain errors, and the receiver aims to decode it to correctly retrieve the sender's original message. In some embodiments, codeword 200 is encoded data (e.g., with an error correction code) transmitted from the sender (e.g., encoder 102) to the receiver via communication channel 104.

Given the bit index 202 ranging from 0 to 9, input codeword 200 includes 10 bits. An LLR 204 for each bit is computed (e.g., by detector 106), which is the soft decision metric or reliability information used in subsequent soft decoding. In some embodiments, the sign (e.g., positive or negative) of LLR value 204 corresponds to a hard decision. For example, a negative sign indicates the corresponding bit is considered to be a “1,” while a positive sign corresponds to a “0” decision. The magnitude of LLR value 204 corresponds to a certainty or likelihood in that decision. In the depicted example of FIG. 2, reliability value 206 is the absolute value of LLR 204.

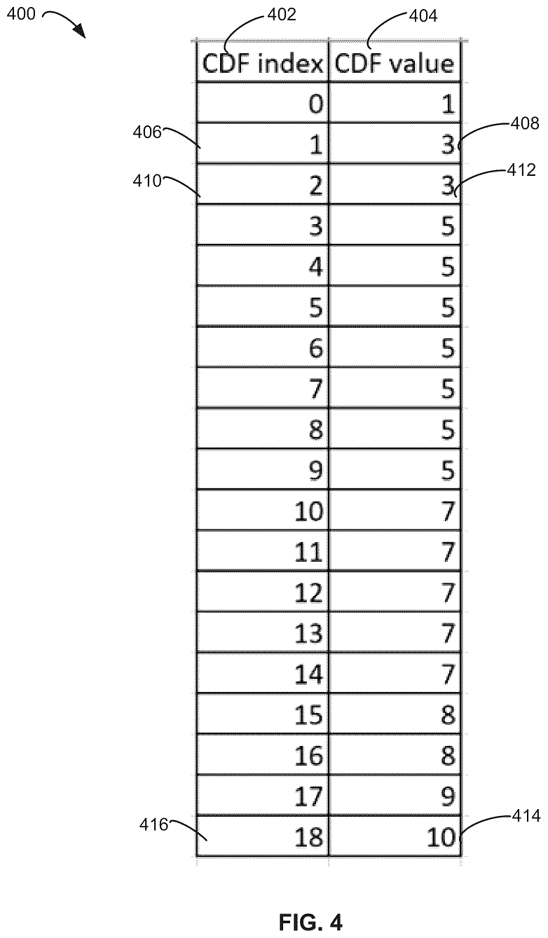

An approach for LRB identification based on generating a cumulative distribution function (CDF) of reliabilities is disclosed herein. In some embodiments, the present approach may allow a receiver (e.g., detector 106 and soft decoder 108 in FIG. 1) to determine a list of values (e.g., reliability value 206 in FIG. 2) of the least reliable bits, and identify, from the list, a maximum value that can be used to determine n LRBs. The maximum value refers to the largest reliability value that is within the LRBs. The maximum value is therefore a maximum LRB value or a LRB threshold. By generating the CDF of the reliabilities in the present system, the receiver can simply scan the CDF to identify the group/bin of bits that have the reliability value within the threshold range (i.e., the maximum LRB value). This is described below in FIGS. 3 and 4. The receiver may then scan the list of LLRs or reliabilities (e.g., list 200 in FIG. 2) to obtain the location of the least reliable bits in the identified group.

FIG. 3 illustrates an exemplary LRB identification result 300 from applying the present approach on codeword 200 of FIG. 2. Result 300 is the list of LRBs for identifying three LRBs from codeword 200 in FIG. 2. In this example, result 300 includes an LRB index 302 and an LRB value 304. LRB index 302 indicates the location/position of each of the three least reliable bits in codeword 200, and LRB value 304 measures the reliability of the corresponding least reliable bit.

The present approach allows the CDF of reliabilities to be built either (1) on the whole sequence of the received codeword, or (2) on a partial sequence of the codeword that has been received at the moment. Since the data decoding may be implemented concurrently when subsequent data (e.g., a new portion of codeword, new codeword) is still in transmission to the receiver, this approach particularly benefits time-sensitive data restoration.

In some embodiments, upon receiving a codeword, a receiver (e.g., detector 106 and soft decoder 108) may first calculate a CDF for this codeword and then use the LRB threshold to identify the LRB locations in the codeword. This approach can be used to easily and efficiently implement iterative decoding. In the present system, the LLRs may be updated from one codeword and written in memory. When decoding a subsequent codeword later, the present system can read LLRs from the memory. Therefore, by maintaining the CDF per codeword in the write process, the present approach may allow the bit or LRB locations to be easily identified when the LLRs are read for the next codeword. Using the present approach, the reliability value of each bit (e.g., LRB value 304) is used only once in the second pass to compare to the specified threshold. The present system calculates the LRBs more efficiently, as compared to a conventional Chase decoder. (In conventional Chase algorithm description determining the LRBs in a first stage of Chase or a preprocessing stage is a matter of arbitrary definition.)

FIG. 4 illustrates an exemplary CDF 400 of reliability values calculated for the exemplary codeword 200 in FIG. 2. A CDF in the present disclosure refers to a cumulative historgram of reliability information. In FIG. 4, each CDF index 402 is the maximum LRB value (i.e., the largest reliability value that is within LRBs). Each CDF value 404 counts the total number of codeword 200's bit(s) that each has a reliability value less than or equal to the corresponding CDF index.

Suppose a CDF index, the largest reliability value that can be within LRBs, is configured to one (e.g., 406). Referring to FIG. 2, only three bits (i.e., bit indexes “2,” “3,” and “7”) have a reliability value of zero or one that is less than or equal to the CDF index “1” in 406. Therefore, the corresponding CDF value is “3” in 408. If the CDF index or the maximum reliability value is set to two as in 410, there are still these three bits that have reliability values less than two, and thus the CDF value in 412 is still “3.” In FIG. 2, the largest reliability value of all bits is 18, and so, the CDF value 414 counts all the “10” bits of codeword 200 when the CDF index is set to “18” in 416.

Based on CDF 400 shown in FIG. 4, the receiver (e.g., soft decoder 108) may identify a specific number of LRBs in codeword 200. In the illustrated example, three LRBs are chosen. This means that the threshold is the first bin with its CDF value larger or equal to three. According to CDF 400, this is bin/group 1 with the CDF index “1” in 406. In other words, this bin includes the least data bits with reliability less than or equal to one. As discussed above, bin 1 includes three bits indexed “2,” “3,” and “7.” This LRB identification result is shown in FIG. 3, where LRB index 302 identifies each of the three least reliable bits, and the LRB value 304 shows the reliability value corresponding to each identified bit.

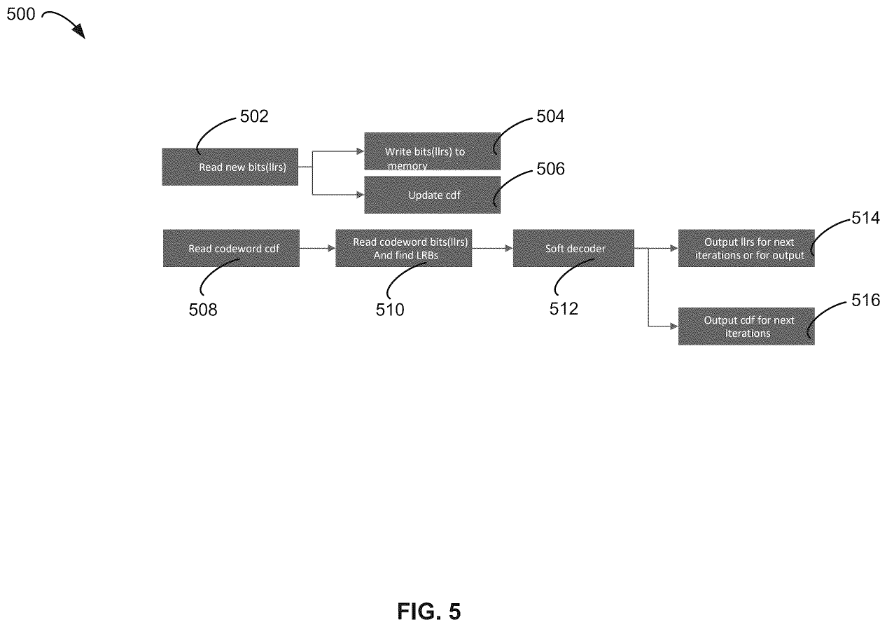

FIG. 5 illustrates an exemplary method 500 for LRB identification. In some embodiments, detector 106 is configured to receive a codeword (e.g., an error-containing codeword encoded with error correction code) and generate reliability information (e.g., LLRs) for the bits included in the codeword. As depicted, new bits of the codeword may be read, and LLRs may be determined at 502. The bits and LLRs can be written to memory at 504. The reliability information such as LLRs can be used as input data of soft decoder 108 to build a CDF for the codeword. The CDF can be written to memory and updated at 506.

As described above in FIGS. 2-4, soft decoder 108 may read the CDF at 508, read the LLRs determined for the codeword bits at 510, and identify and select LRBs based on the CDF and LLRs at 512. Once LRBs are determined, soft decoder 108 may then use the LRBs for performing a decoding process. When iterative decoding is used, soft decoder 108 may output 514 LLRs and output 516 the CDF to be used in the next iteration(s). If the decoding is completed, at 514, soft decoder 108 may also output the retrieved message, which should be the original message from sender 102. The retrieved message is typically extracted from the LLRs by a thresholding operation, i.e. less than zero.

After decoding a codeword, soft decoder 108 will update the CDF. In practice, when soft decoder 108 performs decoding of codewords, the codewords are often interleaved (i.e., the bits being decoded belong to multiple codewords). Typically, soft decoder 108 performs decoding alternatively between the codewords. For example, the decoding of TPC may be performed in rows and then moved to columns. This decoding process repeats until the decoder terminates. To handle the interleaved codewords, the present system is configured to prepare the CDF for the subsequent codeword that is going to be decoded. Continuing the TPC example, suppose the last decoding stage in TPC is by rows, then soft decoder 108 is configured to build a CDF for columns to enable LRB detection for the columns. In particular, since the bits need to be reordered from rows to columns for the decoding, the present system beneficially configures detector 106 and/or soft decoder 108 to calculate and update the CDF after this bits reordering operation.

Therefore, the CDF will be updated when the LLRs are written to memory after an individual current codeword is decoded. Typically in iterative decoding of relevant codes, after a codeword is decoded, the CDF for other codewords which use the same data bit as the other codeword should be updated. However, as described above, the CDF of the current codeword may also be updated. When decoding is performed alternatively by rows and columns in TPC, after a column codeword has been decoded, the CDF for the row codeword should also be updated to prepare for the row decoding, and vice versa. The CDF will be updated during the different iterations.

The CDF of a codeword may be written to memory (e.g., as in 506) or kept in registers. In the present system, once the CDF is determined, it can be replaced by a single number (e.g., CDF threshold value 406 in FIG. 4). This CDF is kept in its entirety until the threshold is determined. For example, if two or three LRBs (i.e., n=2 or n=3) need to be identified, from the CDF list in FIG. 4, the CDF threshold value is “1” as shown in 406. If either of four, five, or six LRBs need to be identified, the threshold value is “2” as shown in 410.

In some embodiments, when the number of LRBs is pre-defined, only the threshold is extracted and stored rather than the whole CDF being kept. In some embodiments, a threshold n is specified. The number of reliabilities, which equals the threshold n, can be used to simplify the comparison of reliabilities and selection of LRB position, by selecting all the bits with reliabilities less than the threshold n and the first nth bits with reliabilities that are equal. Specifically, if n is known (e.g., pre-defined), the CDF value 404 does not need to hold numbers larger than n. As a result, CDF list 400 of FIG. 4 can be truncated. In addition, during the calculation of the CDFs, it may be dynamically determined that certain values are no longer relevant and can thus be discarded. In other words, suppose FIG. 4 includes an intermediate CDF list 400 for n=2, then all rows with CDF index 402 value being greater than one can be discarded, because the threshold is currently “1” and can only stay at one or become zero when more data is added. Based on these considerations used to reduce the size of the CDF list, system performance is improved with more meaningful information stored and used for decoding.

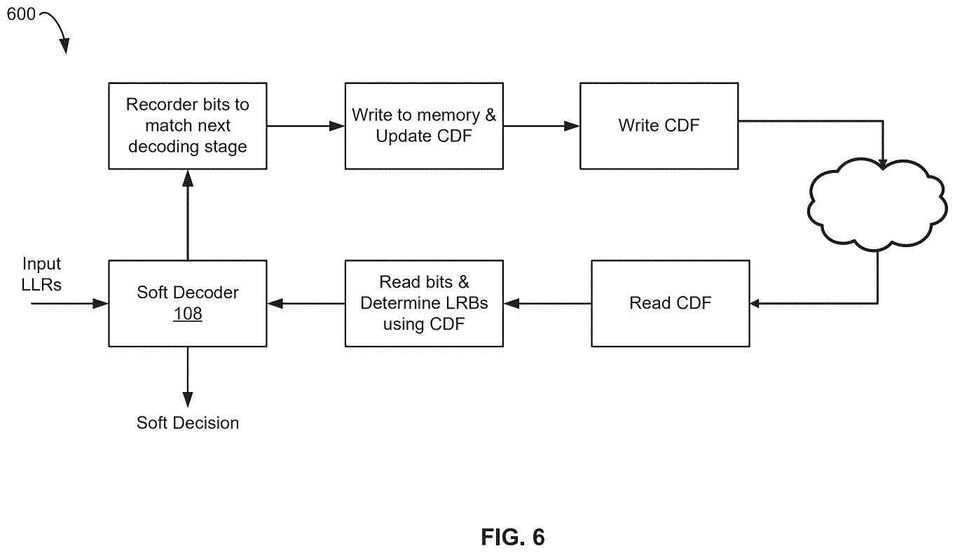

FIG. 6 illustrates an exemplary method 600 of using an oFEC decoder to apply the CDF-based LRB identification described herein. The present LRB-CDF approach is especially suitable for use in oFEC defined in ITU G.709.3. The oFEC is usually run with a small number of bits per LLR. For example, 4 bits per LLR is recommended in the specification of ITU G.709.3. These four bits include 3 bits after an absolute value. This indicates that CDF includes only 2³=8 levels. This also means the easy implementation and high efficiency of applying the present LRB-CDF approach on an oFEC decoder. Since the working flow of using an oFEC decoder to perform the present LRB-CDF approach shown in FIG. 6 is similar to that shown in FIG. 5, the description will not be repeated herein for brevity and clarity.

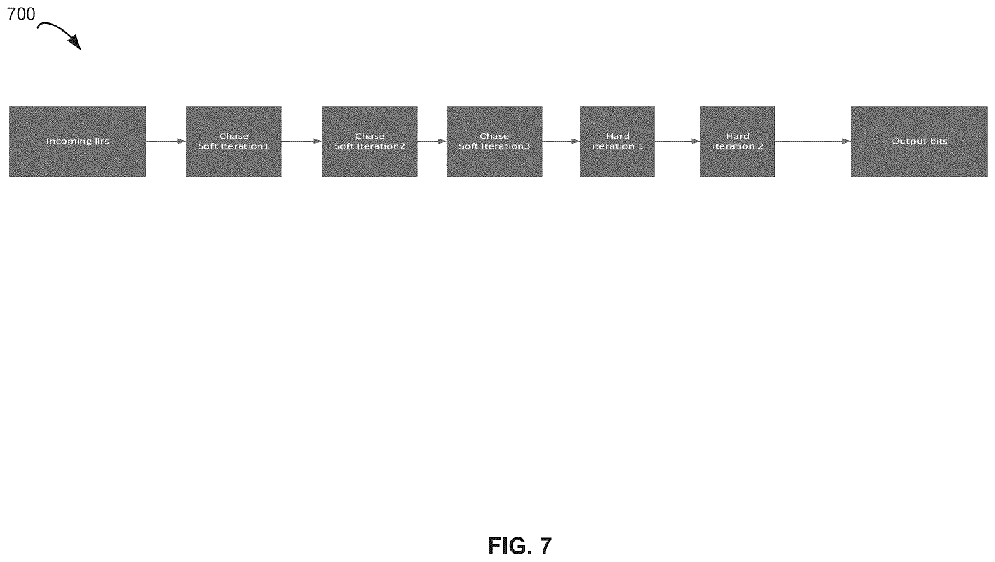

FIG. 7 illustrates an exemplary high level oFEC decoder 700 with three soft iterations and two hard iterations, according to some embodiments. This is a configuration proposed in ITU G.709.3 standard and is also used herein in the present system to show the improved decoding performance.

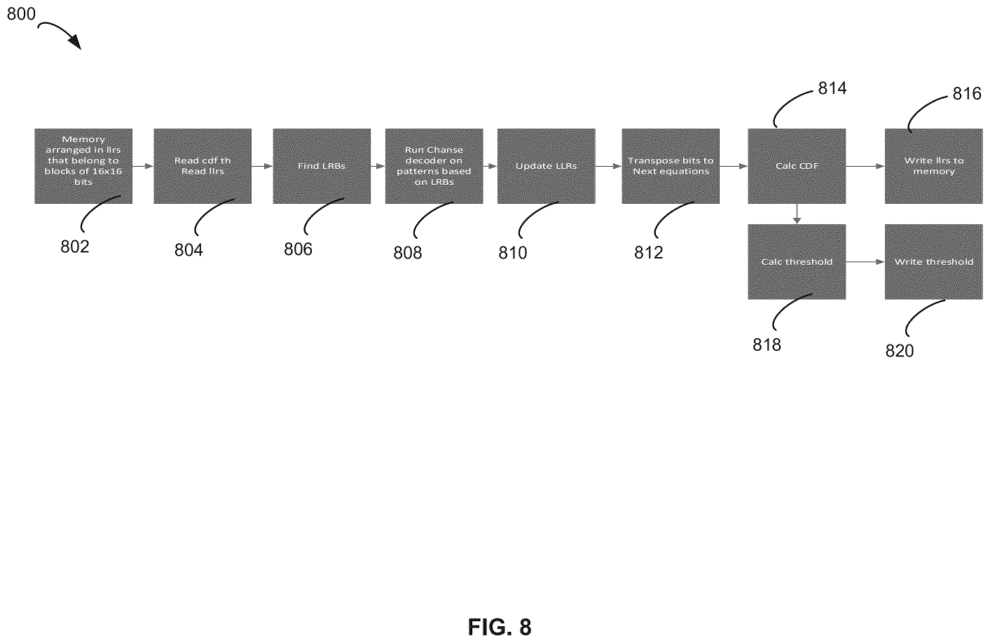

FIG. 8 illustrates an exemplary decoding process 800 using Chase decoding in oFEC decoder. In the depicted example, soft iterations are implemented using a chase decoder, and CDFs are calculated for an oFEC decoder. As shown in 802, a codeword is arranged such that blocks of 16×16 participate in two 16-block equations. Two equations are processed in an alternative order, once in one order and after that in another order. Each bit participates in exactly two equations. The soft decoder works in groups of 16 equations, and the Chase decoder also works in a multiplicity of 16. At 804, the LLRs for the 16 equations are read, and the CDF threshold previously determined is also read. In some embodiments, to find LRBs at 806, the soft decoder reads the LLRs, and during the read, the soft decoder compares the LLRs to the threshold and keeps the values and indices of the LRBs separately. Then the chase decoder runs all the patterns based on the determined LRBs at 808 and updates LLRs at 810 for the next iteration. Next, at 812, the LLRs are permuted to the permuted order of the bits in the equations. Upon the permuted LLRs, the CDFs are calculated at 814, and LLRs are written to memory at 816. After all the LLRs of a codeword have been written, a threshold is determined at 818 and written to memory at 820 to be used in the next iteration.

For oFEC, there is a delay between the read and the write of LLRs, and, thus, the LLR values are usually written to memory. In the example 16×16 blocks shown in oFEC of FIG. 8, since there is a delay between the first equation a bit participates and the second time there is an equation it participates in, the LLRs are written into memory. As a result, there is an opportunity to build the CDF when the LLRs are written to memory.

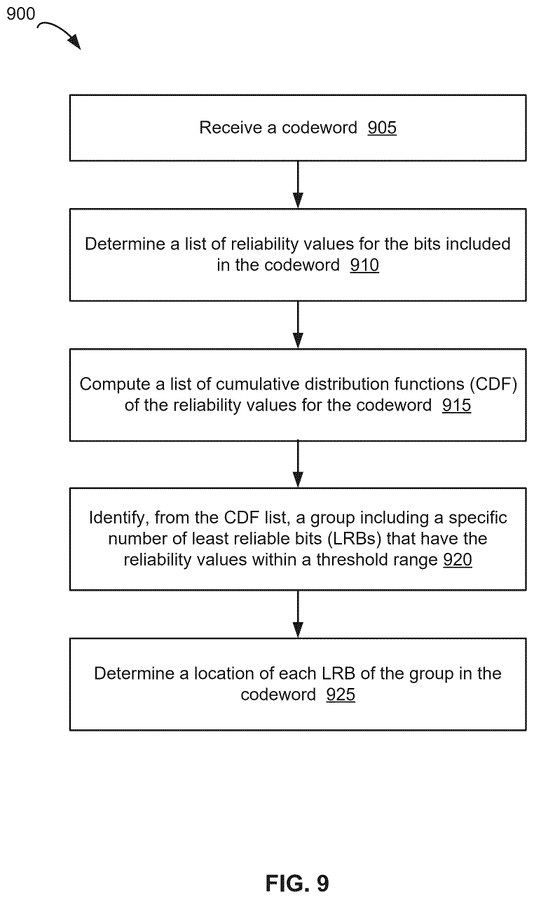

FIG. 9 illustrates an exemplary process 900 for CDF-based LRB identification. In some embodiments, a communication system includes an encoder/sender for transmitting information/message to a receiver via a noisy communication channel. The encoder is configured to encode a codeword with an error correction code and transmit the codeword via the communication channel to the receiver. The receiver is configured to perform the CDF-based LRB identification process 900. In some embodiments, the receiver includes a detector and a soft decoder for implementing steps of process 900.

At step 905, the codeword is received at the receiver. The codeword may contain errors, and the receiver aims to decode it to correctly retrieve the sender's original message.

At step 910, a list of reliability values for the bits included in the codeword is determined. In some embodiments, each of the reliability values is an absolute value of a log likelihood ratio (LLR). The example list of reliability values is shown in FIG. 2.

At step 915, a list of CDF of the reliability values for the codeword is computed. The example CDF list is shown in FIG. 4.

At step 920, a threshold group is identified from the CDF list. The group includes a specific number of LRBs that have the reliability values within a threshold range. In some embodiments, the receiver (e.g., detector 106 and soft decoder 108 in FIG. 1) determines a list of values (e.g., reliability value 206 in FIG. 2) of the least reliable bits, and identifies, from the list, a maximum LRB value that can be used to determine n LRBs. The maximum LRB value refers to the largest reliability value that is within the LRBs. By generating the CDF of the reliabilities in the present system, the receiver can simply scan the CDF to identify the group/bin of bits that have the reliability value within the threshold range (i.e., the maximum LRB value).

At step 925, the location of each LRB in the codeword is determined. The LRBs are included in the identified group/bin. The receiver may scan the list of LLRs or reliabilities (e.g., list 200 in FIG. 2) to obtain the location of these least reliable bits in the codeword. The example result is shown in FIG. 3.

In some embodiments, once the threshold has been determined, there may be more than n bits with reliability values being less or equal to the threshold. There is some freedom on which locations from identified bin/group that the bits can choose. In some embodiments, when creating the CDF, the receiver may be configured to store, along with the threshold, the number or LRBs in the identified bin/group that should be taken. This reduces ambiguity and unnecessary comparisons, thereby further improving decoding performance.

### Additional Considerations

In some implementations, at least a portion of the approaches described above may be realized by instructions that upon execution cause one or more processing devices to carry out the processes and functions described above. Such instructions may include, for example, interpreted instructions such as script instructions, or executable code, or other instructions stored in a non-transitory computer readable medium. The storage device 830 may be implemented in a distributed way over a network, for example as a server farm or a set of widely distributed servers, or may be implemented in a single computing device.

Although an example processing system has been described, embodiments of the subject matter, functional operations and processes described in this specification can be implemented in other types of digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible nonvolatile program carrier for execution by, or to control the operation of, data processing apparatus. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. The computer storage medium can be a machine-readable storage device, a machine-readable storage substrate, a random or serial access memory device, or a combination of one or more of them.

The term “system” may encompass all kinds of apparatus, devices, and machines for processing data, including by way of example a programmable processor, a computer, or multiple processors or computers. A processing system may include special-purpose logic circuitry, e.g., an FPGA (field programmable gate array) or an ASIC (application-specific integrated circuit). A processing system may include, in addition to hardware, code that creates an execution environment for the computer program in question, e.g., code that constitutes processor firmware, a protocol stack, a database management system, an operating system, or a combination of one or more of them.

A computer program (which may also be referred to or described as a program, software, a software application, a module, a software module, a script, or code) can be written in any form of programming language, including compiled or interpreted languages, or declarative or procedural languages, and it can be deployed in any form, including as a standalone program or as a module, component, subroutine, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable computers executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Computers suitable for the execution of a computer program can include, by way of example, general or special purpose microprocessors or both, or any other kind of central processing unit. Generally, a central processing unit will receive instructions and data from a read-only memory or a random access memory, or both. A computer generally includes a central processing unit for performing or executing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few.

Computer readable media suitable for storing computer program instructions and data include all forms of nonvolatile memory, media, and memory devices, including by way of example semiconductor memory devices, e.g., EPROM, EEPROM, and flash memory devices; magnetic disks, e.g., internal hard disks or removable disks; magneto optical disks; and CD-ROM and DVD-ROM disks. The processor and the memory can be supplemented by, or incorporated in special-purpose logic circuitry.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's user device in response to requests received from the web browser.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship between client and server arises by virtue of computer programs running on the respective computers and having a client-server relationship to each other.

While this specification contains many specific implementation details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous. Other steps or stages may be provided, or steps or stages may be eliminated, from the described processes. Accordingly, other implementations are within the scope of the following claims.

The phraseology and terminology used herein is for the purpose of description and should not be regarded as limiting.

The term “approximately”, the phrase “approximately equal to”, and other similar phrases, as used in the specification and the claims (e.g., “X has a value of approximately Y” or “X is approximately equal to Y”), should be understood to mean that one value (X) is within a predetermined range of another value (Y). The predetermined range may be plus or minus 20%, 10%, 5%, 3%, 1%, 0.1%, or less than 0.1%, unless otherwise indicated.

The indefinite articles “a” and “an,” as used in the specification and in the claims, unless clearly indicated to the contrary, should be understood to mean “at least one.” The phrase “and/or,” as used in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of or “exactly one of,” or, when used in the claims, “consisting of,” will refer to the inclusion of exactly one element of a number or list of elements. In general, the term “or” as used shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

The use of “including,” “comprising,” “having,” “containing,” “involving,” and variations thereof, is meant to encompass the items listed thereafter and additional items.

Use of ordinal terms such as “first,” “second,” “third,” etc., in the claims to modify a claim element does not by itself connote any priority, precedence, or order of one claim element over another or the temporal order in which acts of a method are performed. Ordinal terms are used merely as labels to distinguish one claim element having a certain name from another element having a same name (but for use of the ordinal term), to distinguish the claim elements.

Having thus described several aspects of at least one embodiment of this invention, it is to be appreciated that various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A receiver in a communication system for identifying least reliable bits (LRBs), the receiver comprising:
a detector configured to receive a codeword and determine a list of reliability values for the bits included in the codeword; and
a decoder coupled to the detector and configured to:
receive, from the detector, the codeword and the list of reliability values;
compute a list of cumulative distribution functions (CDF) of the reliability values for the codeword;
identify, from the CDF list, a group including a specific number of LRBs that have the reliability values within a threshold range; and
determine a location of each LRB of the group in the codeword.

2. The receiver of claim 1, wherein a reliability value of the reliability values is an absolute value of a log likelihood ratio (LLR).

3. The receiver of claim 1, wherein the decoder is further configured to decode the codeword based on the identified LRBs and locations associated with the LRBs.

4. The receiver of claim 3, wherein the decoder is further configured to update the CDF after decoding the codeword, wherein to update the CDF, the decoder is further configured to prepare the CDF for a subsequent codeword to be decoded.

5. The receiver of claim 3, wherein the decoder is further configured to:
update the LLRs for the codeword; and
write the LLRs in memory.

6. The receiver of claim 5, wherein the decoder is further configured to read the LLRs from the memory when decoding a next codeword at a later time.

7. The receiver of claim 1, wherein the decoder is an open forward error correction (oFEC) decoder, and the oFEC decoder is configured to build the CDF when writing the LLRs to memory.

8. The receiver of claim 1, wherein the decoder is further configured to build the CDF on an entire sequence of the codeword or a partial sequence of the codeword.

9. The receiver of claim 1, wherein the receiver uses a two-pass algorithm to simplify LRB identification process, wherein the two-pass algorithm is achieved when decoding processing is separated between write and read operations.

10. The receiver of claim 1, wherein the codeword is encoded with an error correction code, and the detector is configured to receive the codeword from an encoder via a communication channel.

11. A method identifying least reliable bits (LRBs) by a receiver comprising:
receiving a codeword encoded with an error correction code;
determining a list of reliability values for the bits included in the codeword;
computing a cumulative distribution function (CDF) of the reliability values for the codeword;
identifying, from the CDF, a group including a specific number of LRBs that have the reliability values within a threshold range; and
determining a location of each LRB of the group in the codeword.

12. The method of claim 11, wherein a reliability value of the reliability values is an absolute value of a log likelihood ratio (LLR).

13. The method of claim 11, further comprising decoding the codeword based on the identified LRBs and locations associated with the LRBs.

14. The method of claim 13, further comprising:
updating the CDF after decoding the codeword,
wherein the updating comprises preparing the CDF for a subsequent codeword to be decoded.

15. The method of claim 13, further comprising:
updating the LLRs for the codeword; and
writing the LLRs in memory.

16. The method of claim 15, further comprising reading the LLRs from the memory when decoding a next codeword at a later time.

17. The method of claim 11, further comprising building the CDF when writing the LLRs to memory by an open forward error correction (oFEC) decoder.

18. The method of claim 11, further comprising building the CDF on an entire sequence of the codeword or a partial sequence of the codeword.

19. The method of claim 11, wherein identifying the LRBs is simplified using a two-pass algorithm, wherein the two-pass algorithm is achieved when decoding processing is separated between write and read operations.

20. The method of claim 11, wherein the receiver comprises a detector and a soft decoder, wherein the receiver receives the encoded codeword from an encoder via a communication channel.
